(19) United States
(12) Patent Application Publication
(10) Pub. No.: US 2020/0273954 A1
(43) Pub. Date: Aug. 27, 2020

(54) SWITCHING ELEMENT AND METHOD OF MANUFACTURING THE SAME

(71) Applicants: Tatsuji NAGAOKA, Nagakute-shi (JP); Hiroyuki NISHINAKA, Kyoto-shi (JP); Masahiro YOSHIMOTO, Kyoto-shi (JP)

(72) Inventors: Tatsuji NAGAOKA, Nagakute-shi (JP); Hiroyuki NISHINAKA, Kyoto-shi (JP); Masahiro YOSHIMOTO, Kyoto-shi (JP)

(73) Assignees: TOYOTA JIDOSHA KABUSHIKI KAISHA, Toyota-shi (JP); NATIONAL UNIVERSITY CORPORATION KYOTO INSTITUTE OF TECHNOLOGY, Kyoto-shi (JP)

(21) Appl. No.: 16/750,739

(22) Filed: Jan. 23, 2020

(30) Foreign Application Priority Data
Feb. 27, 2019 (JP) 2019-033990

(51) Int. Cl. H01L 29/24; H01L 29/04; H01L 29/66; H01L 29/78; H01L 29/423; H01L 29/06

(52) U.S. Cl. CPC H01L 29/24; H01L 29/04; H01L 29/0696; H01L 29/78; H01L 29/4236; H01L 29/66969

(57) ABSTRACT

A switching element may include: a gallium oxide substrate constituted of a gallium oxide crystal; and a plurality of gate electrodes facing the gallium oxide substrate via a gate insulating films. An upper surface of the gallium oxide substrate is parallel to a (010) plane of the gallium oxide crystal, and in a plan view of the upper surface of the gallium oxide substrate, a longitudinal direction of each gate electrode intersects a direction along which a (100) plane of the gallium oxide crystal extends.

### CROSS-REFERENCE TO RELATED APPLICATION

This application claims priority to Japanese Patent Application No. 2019-033990 tiled on Feb. 27, 2019, the contents of which are hereby incorporated by reference into the present application.

### TECHNICAL FIELD

The technology herein disclosed relates to a switching element and a method of manufacturing the same.

### BACKGROUND

Japanese Patent Application Publication No. 2016-164906 describes a switching element including a gallium oxide substrate. This switching element includes a plurality of gate electrodes facing the gallium oxide substrate via a gate insulating film.,

### SUMMARY

A gallium oxide crystal has a thermal conductivity higher in a [010] direction than in. other directions. In a switching element, having an upper surface of a gallium. oxide substrate be a (010) plane, therefore, allows for efficient heat dissipation from the upper surface. On the other hand., in the gallium oxide crystal, cleavage is prone to occur at a (100) plane. If the upper surface of the gallium oxide substrate is made the (010) plane, therefore, there is a problem where cracks are likely to occur in the gallium oxide substrate along the (100) plane (i.e., a plane surface. perpendicular to the upper surface). The present specification proposes a technology of suppressing cracks in a switching element that includes a gallium oxide substrate, an upper surface of which is constituted of a (010) plane.

A switching element disclosed herein may comprise: a gallium oxide substrate constituted of a gallium oxide crystal; and a plurality of gate electrodes facing the gallium oxide substrate via a gate insulating film, wherein an upper surface of the gallium oxide substrate is parallel to a (010) plane of the gallium oxide crystal., and in plan view of the upper surface of the gallium oxide substrate, a longitudinal direction of each gate electrode intersects a direction along which a (100) plane of the gallium oxide crystal extends.

Since this switching element has its upper surface of the gallium oxide substrate that is parallel to the (010) plane, the switching element can efficiently dissipate heat from the upper surface. Moreover, in this switching element, in the plan view of the upper surface of the gallium oxide substrate, the longitudinal direction of each gate electrode intersects the direction along which the (100) plane extends (i.e., a direction along which cracks are likely to occur). Each gate electrode extends to intersect the direction along which the (100) plane extends, and thus cracks are avoided from occurring along the (100) plane.

### BRIEF DESCRIPTION OF DRAWINGS

FIG. 1 is a diagram showing a unit cell of a gallium oxide crystal;

FIG. 2 is a top view of a switching element in a first embodiment;

FIG. 3 is a cross-sectional view taken along a line III-III in FIG. 2;

FIG. 4 is a top view of a switching element in a second embodiment;

FIG. 5 is a cross-sectional view taken along a line V-V in FIG. 4;

FIG. 6 is a top view of a switching element in a third embodiment; and

FIG. 7 is a cross-sectional view taken along a line VII-VII in FIG. 6 (a cross-sectional view of the switching element in a packaged state).

### DETAILED DESCRIPTION

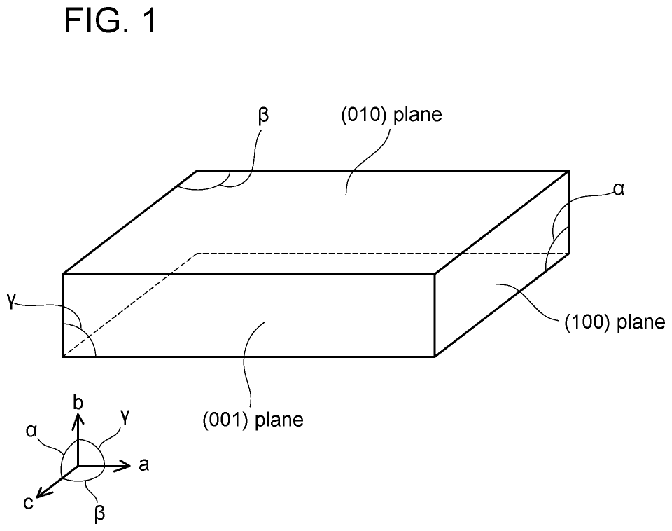

Initially, a gallium oxide crystal will be described, FIG. 1 shows a unit cell of the gallium oxide crystal. Each of an angle γ between a crystallographic axis a and a crystallographic axis b, and an angle α between the crystallographic axis b and a crystallographic axis c is 90 degrees. An angle β between the crystallographic axis c and the crystallographic axis a is 104 degrees. In other words, the gallium oxide crystal is monoclinic. The crystallographic axis a has a length of approximately 1.22 nm, the crystallographic axis b has a length of approximately 0.30 nm, and the crystallographic axis c has a length of approximately 0.58 nm. The gallium oxide crystal tends to cleave along a (100) plane parallel to the crystallographic axis b and the crystallographic axis c, The gallium oxide crystal thus tends to have cracks along the (100) plane. Moreover, the gallium oxide crystal has a thermal conductivity higher in a direction parallel to the crystallographic axis b than in other directions.

### First Embodiment

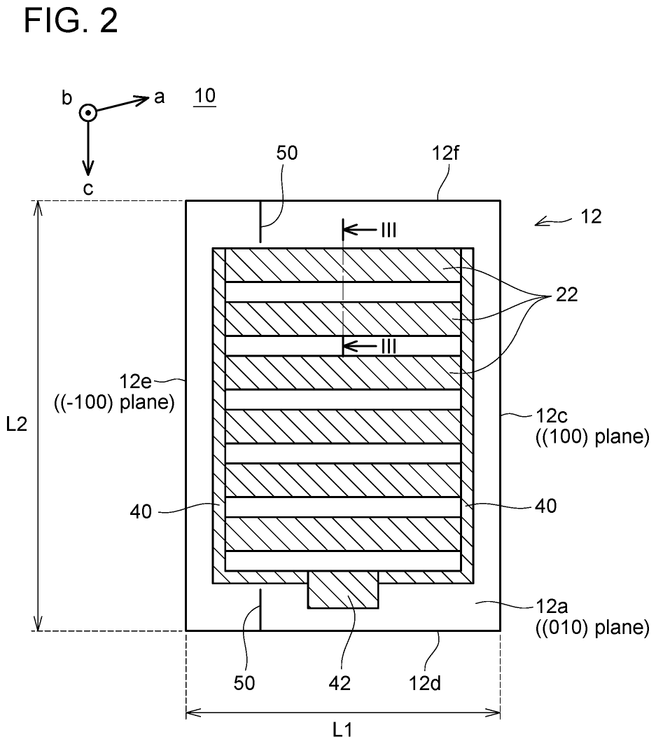

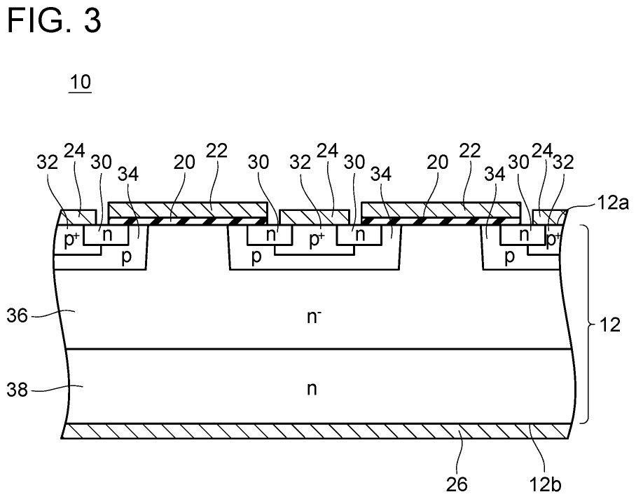

FIGS. 2 and 3 show a switching element 10 in a first embodiment. The switching element 10 comprises a gallium oxide substrate 12. The gallium oxide substrate 12 has a rectangular-plate shape, and includes an. upper surface 12a, a lower surface 12b, and four side surfaces 12c to 12f. The upper surface 12a is constituted of a (010) plane. The lower surface 12b is constituted of a (0−10) plane, In other words, the upper surface 12a and the lower surface 12b are parallel to the (010) plane. The side surface 12c is constituted of the (100) plane. The side surface 12e is constituted of a (−100) plane. In other words, the side surface 12c and the side surface 12e are parallel to the. (100) plane, The side surface 12d is perpendicular to the upper surface 12a, the lower surface 12b, the side surface 12c, and the side surface 12e. The side surface 12f is perpendicular to the upper surface 12a, the lower surface 12b, the side surface 12c, and the side surface 12e.

As shown in FIG. 3, a plurality of gate insulating films 20, a plurality of gate electrodes 22, and a plurality of source electrodes 24 are provided above the upper surface 12a of the gallium oxide substrate 12. FIG. 2 omits illustration of the source electrodes 24.

As shown. in FIG. 3, each gate insulating film 20 covers a part of the upper surface 12a of the gallium oxide substrate 12. Each gate electrode 22 covers an upper surface of corresponding one of the gate insulating films 20. Each gate electrode 22 is insulated from the gallium oxide substrate 12 by the corresponding gate insulating film 20. In other words, each gate electrode 22 faces the gallium oxide substrate 12 via the corresponding gate insulating film 20. As shown in FIG. 2, in a plan view of the upper surface 12a of the gallium oxide substrate 12, each gate electrode 22 extends linearly along a direction perpendicular to the side surface 12c, In other words, in the plan. view of the upper surface 12a of the gallium oxide substrate 12, a longitudinal direction of each gate electrode 22 intersects a direction along which the (100) plane extends (i.e., a direction of the crystallographic axis c). The plural gate electrodes 22 are arranged at intervals in a direction along which the side surface 12c extends. A gate wiring 40 and a gate pad 42 are provided above the upper surface 12a of the gallium oxide substrate 12. The gate wiring 40 and the gate pad 42 are insulated from the gallium oxide substrate 12 by an interlayer insulating film not shown. The gate wiring 40 is connected to an end of each gate electrode 22 in its longitudinal direction. The gate wiring 40 connects each gate electrode 22 to the gate pad 42.

As shown in FIG. 3, each source electrode 24 is located between corresponding adjacent gate electrodes 22. Each source electrode 24 is in contact with the upper surface 12a of the gallium oxide substrate 12.

A drain electrode 26 is provided to be in contact with the lower surface 12b of the gallium oxide substrate 12. The drain electrode 26 covers an entirety of the lower surface 12b of the gallium oxide substrate 12.

A plurality of source regions 30, a plurality of body contact regions 32, a plurality of body regions 34, a drift region 36, and a drain region 38 are disposed inside the gallium oxide substrate 12.

Each source region 30, which is of an n-type, is located at a position that is in contact with corresponding one of the source electrodes 24 and corresponding one of the gate insulating films 20. Each source region 30 is in ohmic contact with the corresponding source electrode 24.

Each body contact region 32, which is of a p-type, is located below corresponding one of the source electrodes 24. Each body contact region 32 is in ohmic contact with the corresponding source electrode 24.

Each body region 34 is located around corresponding one of the source regions 30 and corresponding one of the body contact regions 32. Each body region 34 is of a p-type, and has a lower p-type impurity concentration than the body contact regions 32, Each body region 34 is in contact with corresponding ones of the gate insulating films 20 next to the corresponding source regions 30.

The drift region 36 is of an n4ype, and is located laterally to and under the body regions 34. The drift region 36 is in contact with. the gate insulating films 20 adjacently to the body regions 34. The drift region 36 is separated from the source regions 30 by the body regions 34.

The drain region 38 is of an. n-type, and has a higher n-type impurity concentration than the drift region 36. The drain region 38 is located under the drift region 36. The drain region 38 is in ohmic contact with the drain electrode 26.

The gate insulating films 20, the gate electrodes 22, the source electrodes 24, the drain electrode 26, the source regions 30, the body contact regions 32, the body regions 34, the drift region 36, and the drain region 38 form n-channel-type metal oxide semiconductor field effect transistors (MOSFETs).

When the switching element 10 (i.e., the MOSFET(s)) operates, the gallium oxide substrate 12 generates heat. As mentioned above, the gallium oxide crystal has a thermal conductivity high in the direction parallel to the crystallographic axis b. Moreover, as mentioned above, each of the upper surface 12a and the lower surface 12b of the gallium oxide substrate 12 is constituted of a plane parallel to the (010) plane (i.e., a plane perpendicular to the crystallographic axis b). The heat generated in the gallium oxide substrate 12 thus easily transfers to the source electrodes 24 and the drain electrode 26. Therefore, a temperature rise in the switching element 10 can be suppressed.

As mentioned above, the gallium oxide crystal is likely to have cracks along the (100) plane. For example, as in a straight line 50 in FIG. 2, cracks are prone to occur from the side surface 12d or the side surface 12f along the (100) plane. In the switching element 10 in the first embodiment, however, as shown in FIG. 2, the plurality of gate electrodes 22 extends along a direction intersecting the direction along which the (100) plane extends. The gallium oxide substrate 12 is reinforced with the gate electrodes 22, by which cracks are avoided from occurring in the gallium oxide substrate 12 along the (100) plane. Therefore, in the switching element 10 in the first embodiment, occurrence of cracks in the gallium oxide substrate 12 is suppressed while the switching element 10 is being manufactured or used.

Moreover, as shown in FIG. 2, in the plan view of the upper surface 12a of the gallium oxide substrate 12, the side surfaces 12d, 12f are shorter than the side surfaces 12c, 12e. In other words, a length L1 of the gallium oxide substrate 12 in a direction perpendicular to the (100) plane is shorter than a length L2 of the gallium oxide substrate 12 in the direction along the (100) plane. By making the length L1 of the gallium oxide substrate 12 in the direction perpendicular to the (100) plane short and making the length L2 of the gallium oxide substrate 12 in the direction along the (100) plane long, as such, the occurrence of cracks in the gallium oxide substrate 12 along the (100) plane is further suppressed,

### Second Embodiment

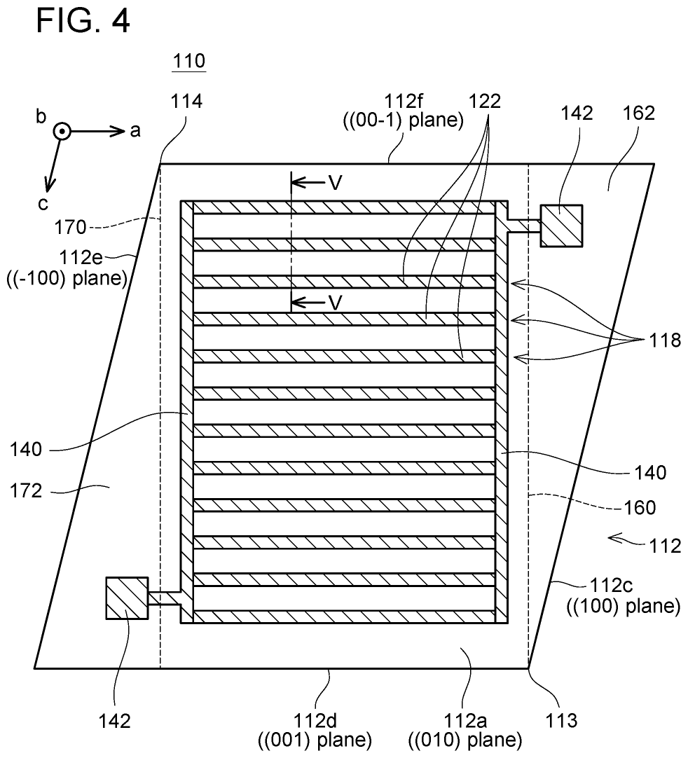

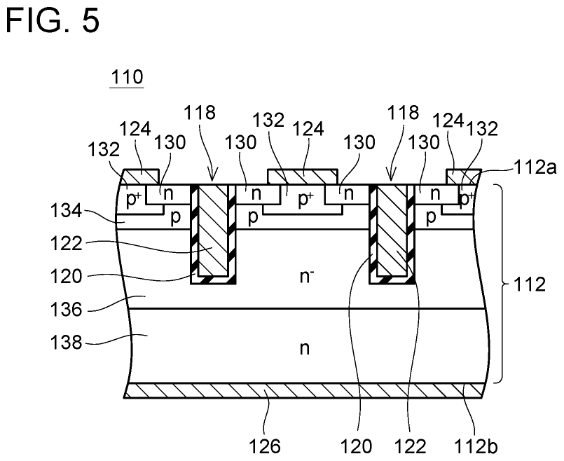

FIGS. 4 and 5 show a switching element 110 in a second embodiment. The switching element 110 comprises a gallium oxide substrate 112. The gallium oxide substrate 112 has a parallelogrammatic-plate shape. The gallium oxide substrate 112 includes an upper surface 112a, a lower surface 112b, a side surface 112c, a side surface 112d, a side surface 112; and a side surface 112f. The upper surface 112a is constituted of the (010) plane. The lower surface 112b is constituted of the (0−10) plane, The side surface 112c is constituted of the (100) plane. The side surface 112e is constituted of the (−100) plane. The side surface 112d is constituted of a (001) plane. The side surface 112f is constituted of a (00-1) plane. In other words, the side surface 112d and the side surface 112f are parallel to the (001) plane.

As shown in FIG. 5, a plurality of trenches 118 is disposed in the upper surface 112a of the gallium oxide substrate 112. A gate insulating film 120 and a gate electrode 122 are disposed in each trench 118, Moreover, a plurality of source electrodes 124 is disposed on the upper surface 112a of the gallium oxide substrate 112. FIG. 4 omits illustration of the source electrodes 124.

As shown in FIG. 4, each trench 118 extends, in the upper surface 112a of the gallium oxide substrate 112, linearly along a direction along which the (001) plane extends, The plural trenches 118 are disposed at intervals in a direction perpendicular to the (001) plane. As shown in FIG. 5, each gate insulating film 120 covers an inner surface of corresponding one of the trenches 118. Each gate electrode 122 is located in corresponding one of the trenches 118, and covers a surface of corresponding one of the gate insulating films 120, Each gate electrode 122 is insulated from the gallium oxide substrate 112 by the corresponding gate insulating film 120. In other words, each gate electrode 122 faces the gallium oxide substrate 112. via the corresponding gate insulating film 120. Each gate electrode 122 extends along the corresponding trench 118. In other words, as shown in FIG. 4, in a plan view of the upper surface 112a of the gallium oxide substrate 112, each gate electrode 122 extends linearly along the direction along which the (001) plane extends. In other words, in the plan view of the upper surface 112a of the gallium oxide substrate 112, a longitudinal direction of each gate electrode 122 intersects the direction along which the (100) plane extends (i.e., the direction of the crystallographic axis c). Gate wirings 140 and gate pads 142 are disposed above the upper surface 112a of the gallium oxide substrate 112. The gate wirings 140 and the gate pads 142 are insulated from the gallium oxide substrate 112 by an interlayer insulating film not shown. Each gate wiring 140 is connected to an end of each gate electrode 122 in its longitudinal direction. The gate wirings 140 connect each gate electrode 122 to the respective gate pads 142.

A straight line 160 in FIG. 4 represents a straight line extending from a connection spot 113 of the side surface 112c and the side surface 112d along a direction perpendicular to the side surface 112d. Since the upper surface 112a of the gallium oxide substrate 112 has a parallelogrammatic shape, a triangular region 162 exists between the straight line 160 and the side surface 112c in the plan view of the upper surface 112a. One of the gate pads 142 is located in the region 162 among the upper surface 112a. Forming gate electrode(s) 122 in the triangular region 162 is difficult. For example, if the gate electrode(s) 122 are formed in the region 162, electric field concentration would occur in vicinity of the gate electrode(s) 122 in the region 162. By not providing the gate electrode(s) 122 in the region. 162, as in FIG. 4, a withstand voltage of the switching element 110 can be improved. Moreover, providing the gate pad 142 in the region 162 allows effective use of the region 162, and accordingly downsizing of the switching element 110. Moreover, a straight line 170 in FIG. 4 represents a straight line extending from a connection spot 114 of the side surface 112e and the side surface 112f along direction perpendicular to the side surface 112f. In the plan view of the upper surface 112a, a triangular region 172 exists between the straight line 170 and the side surface 112e. Another one of the gate pads 142 is located in the region 172 among the upper surface 112a. Providing the gate pad 142 in the region 172 allows effective use of the region 172, and accordingly downsizing of the switching element 110.

As shown in FIG. 5, each source electrode 124 is located between corresponding adjacent gate electrodes 122. Each source electrode 124 is in contact with the upper surface 112a of the gallium oxide substrate 112.

A drain electrode 126 is provided to be in contact with the lower surface 112b of the gallium oxide substrate 112. The drain electrode 126 covers an entirety of the lower surface 112b of the gallium oxide substrate 112.

A plurality of source regions 130, a plurality of body contact regions 132, a body region 134, a drift region 136, and a drain region 138 are disposed inside the gallium oxide substrate 112.

Each source region 130 is of an n-type, and is located at a position that is in contact with corresponding one of the source electrodes 124 and corresponding one of the gate insulating films 120. Each source region 130 is in contact with the corresponding gate insulating film 120 at an upper end part of corresponding one of the trenches 118. Each source region 130 is in ohmic contact with the corresponding source electrode 124.

Each body contact region 132 is of a p-type, and is located below corresponding one of the source electrodes 124. Each body contact region 132 is in ohmic contact with the corresponding source electrode 124.

The body region 134 is located under the source regions 130 and the body contact regions 132. The body region 134 is of a p-type, and has a lower p-type impurity concentration than the body contact regions 132. The body region 134 is in contact with the gate insulating films 120 under the corresponding source regions 130.

The drift region 136 is of an n-type, and is located under the body region 134. The drift region 136 is in contact with the gate insulating films 120 under the body region 134. The drift region 136 is separated from the source regions 130 by the body region 134.

The drain region 138 is of an n-type, and has a higher n-type impurity concentration than the drift region 136. The drain region 138 is located under the drift region 136. The drain region 138 is in ohmic contact with the drain electrode 126.

The gate insulating films 120, the gate electrodes 122, the source electrodes 124, the drain electrode 126, the source regions 130, the body contact regions 132, the body region 134, the drift region 136, and the drain region 138 form n-channel-type MOSFETs.

When the switching element 110 operates, the gallium oxide substrate 112 generates heat. As mentioned above, the gallium oxide crystal has a thermal conductivity high in the direction parallel to the crystallographic axis b. Moreover, as mentioned above, each of the upper surface 112a and the lower surface 112b of the gallium oxide substrate 112 is constituted of the plane parallel to the (010) plane (i.e., the plane perpendicular to the crystallographic axis b). The heat generated in the gallium oxide substrate 112 thus is likely to be transferred to the source electrodes 124 and the drain. electrode 126. Therefore, a temperature rise in the switching element 110 can be suppressed.

As mentioned above, the gallium oxide crystal tends to have cracks along the (100) plane. In the switching element 110 in the second embodiment, however, as shown in FIG. 4, the plurality of gate electrodes 122 extends along the direction intersecting the direction along which the (100) plane extends, The gallium oxide substrate 112 is reinforced with the gate electrodes 122, by which the occurrence of cracks in the gallium oxide substrate 112 along the (100) plane is suppressed. Therefore, the switching element 110 in the second embodiment suppresses the occurrence of cracks in the gallium oxide substrate 112 while the switching element 110 is being manufactured or used.

### Third Embodiment

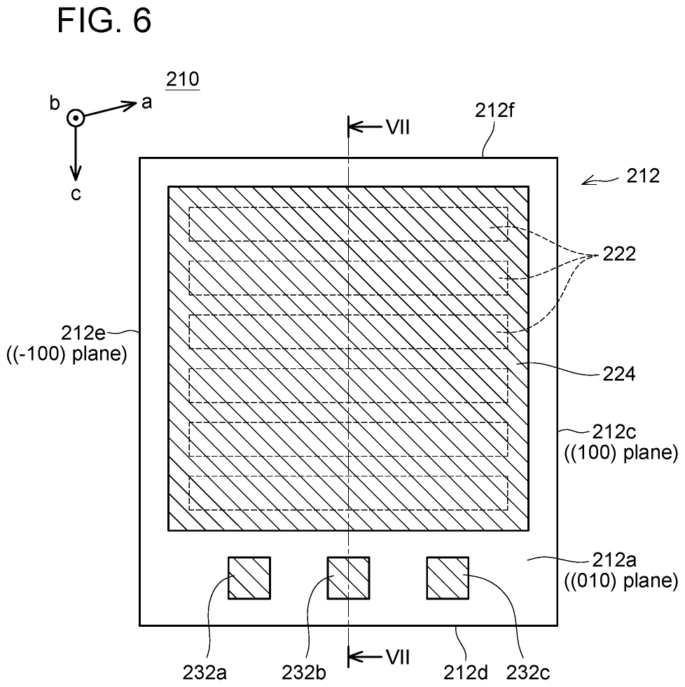

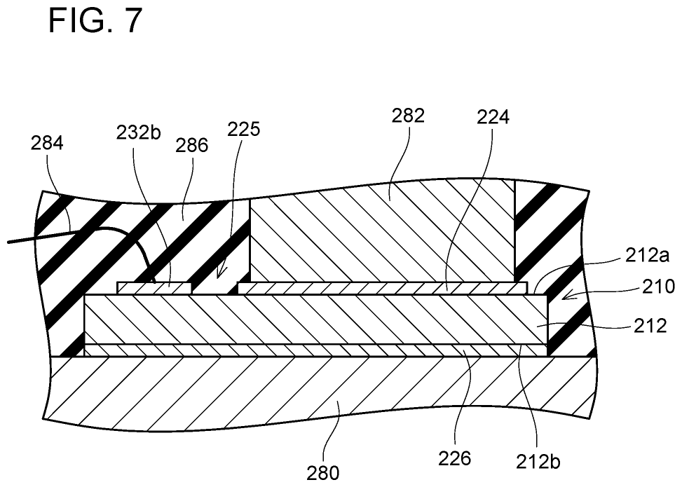

FIGS. 6 and 7 show a switching element 210 in a third embodiment. The switching element 210 comprises a gallium oxide substrate 212. The gallium oxide substrate 212 has a rectangular-plate shape, and includes an upper surface 212a, a lower surface 212b, a side surface 212c, a side surface 212d, a side surface 212e, and a side surface 212f. The upper surface 212a is constituted of a (010) plane. The lower surface 212b is constituted of a (0−10) plane. The side surface 212c is constituted of a (100) plane. The side surface 212e is constituted of a (−100) plane. The side surface 212d is perpendicular to the upper surface 212a, the lower surface 212b, the side surface 212c, and the side surface 212e. The side surface 212f is perpendicular to the upper surface 212a, the lower surface 212b, the side surface 212c, and the side surface 212e.

As shown in FIG. 6, a plurality of gate electrodes 222 is disposed in the gallium oxide substrate 212. The gate electrodes 222 may be located on the upper surface 212a, similarly to the gate electrodes 22 in the first embodiment, or may be located in trenches, similarly to the gate electrodes 122 in the second embodiment. In the switching element 210 in the third embodiment, a source electrode 224 is located to cover the respective gate electrodes 222. The source electrode 224 is insulated from each gate electrode 222 by an interlayer insulating film not shown. The source electrode 224 is in contact with the upper surface 212a of the gallium oxide substrate 212 in a range where the gate electrodes 222 do not exist. Moreover, a plurality of electrode pads 232a to 232c is disposed above the upper surface 212a of the gallium oxide substrate 212. The electrode pad 232b is a gate pad. The gate pad 232b is connected to each gate electrode 222 by a gate wiring not shown. The electrode pads 232a to 232c are located at positions spaced apart from the source electrode 224 in the direction of the crystallographic axis c (i.e., the direction along which the (100) plane extends). The switching element 210 in the third embodiment, as in the first and second embodiments, includes a structure of n-channel-type MOSFETs. In the switching element 210 in the third embodiment as well, since the upper surface 212a and the lower surface 212b are parallel to the (010) plane, the switching element 210 can efficiently dissipate heat from the gallium oxide substrate 212 while the switching element 210 is operating. Moreover, in a plan view of the upper surface 212a of the gallium oxide substrate 212 as shown in FIG. 6, each gate electrode 222 extends linearly along the direction intersecting the direction along which the (100) plane extends. Therefore, the switching element 210 in the third embodiment also suppresses occurrence of cracks in the gallium oxide substrate 212 along the (100) plane,

FIG. 7 shows a cross-sectional view of the switching element 210 in the third embodiment in a packaged state. A drain electrode 226 of the switching element 210 is connected to a lead frame 280. The source electrode 224 of the switching element 210 has a metal block 282 connected thereto. The gate pad 232b has a bonding wire 284 connected thereto. The switching element 210 is encapsulated in an insulating resin. 286.

As shown in FIG. 7, no electrode is provided in a spacing 225 between the gate pad 232b and the source electrode 224. Thus, before formation. of the insulating resin 286, the upper surface 212a of the gallium oxide substrate 212 is exposed at the spacing 225. The spacing 225 is thus recessed in a groove shape relative to a surface of the gate pad 232b and a surface of the source electrode 224, The spacing 225 which is recessed in the groove shape tends to suffer from stress concentration when the switching element 210 is actually mounted. Moreover, when the insulating resin 286 thermally expands during use of the switching element 210, stress is applied. to the gallium oxide substrate 212. High stress is applied particularly to the spacing 225 positioned at a boundary between a range covered with the thick metal block 282 and. a range not covered with the metal block 282. As such, the spacing 225 is prone to suffer from application of high stress. If a direction along which the spacing 225 extends coincides with the direction along which the gallium oxide substrate 212 easily cleaves (i.e., the direction along which the (100) plane extends), cracks are significantly likely to occur in the spacing 225. In contrast to this, the third embodiment allows, as shown in FIG. 6, the spacing 225 to extend along the side surface 212d. In other words, the spacing 225 extends along the direction perpendicular to the (100) plane. In other words, the direction along which the spacing 225 extends intersects (more specifically, is orthogonal to) the direction along which the (100) plane extends. This suppresses occurrence of cracks in the spacing 225.

The switching elements in the first to third. embodiments have been described above. In a course of manufacturing the switching elements in the first to third embodiments, each switching element may be manufactured from a gallium oxide wafer having a diameter of 2 inches or more, In this case, a process of thinning the gallium oxide wafer may be performed by polishing a surface (e.g., a lower surface) of the gallium oxide wafer. Use of a gallium oxide wafer having a large diameter and a small thickness as such, is further likely to cause cracks in the gallium oxide wafer during the manufacturing. By applying the technology of suppressing cracks described. in the first to third embodiments to such manufacturing process, cracks in the gallium oxide wafer can be effectively suppressed.

A relation between components in the above-mentioned embodiments and components in the claims will hereinafter be described. The side surface 112c in the second embodiment is an example of a first side surface in the claims. The side surface 112d in the second embodiment is an example of a second side surface in the claims. Each of the side surfaces 212c, 212e in the third embodiment is an example of a third side surface in the claims. Each of the side surfaces 212d, 212f in the third embodiment is an example of a fourth side surface in the claims.

Some of the technical features herein disclosed will be enumerated below. The following technical elements are independently useful.

In an example of the switching element disclosed herein, a plurality of trenches may be provided in the upper surface of the gallium oxide substrate. In the plan view of the upper surface of the gallium oxide substrate, a longitudinal direction of each trench may intersect the direction along which the (100) plane extends. Each of the gate electrodes may be located in a corresponding one of the trenches.

This configuration can suppress cracks in a gallium oxide substrate in a switching element that includes trench-type gate electrodes.

An example of the switching element disclosed herein may further comprise a gate pad located above the upper surface of the gallium oxide substrate and connected to each gate electrode. Further, the gallium oxide substrate may comprise: a first side surface constituted of the (100) plane; and a second side surface constituted of a (001) plane of the gallium oxide crystal. In the plan view of the upper surface of the gallium oxide substrate, the gate pad may be located within a range between a straight line and the first side surface, the straight line extending from a connection of the first side surface and the second side surface along a direction perpendicular to the second side surface.

Since the gallium oxide crystal has a monoclinic crystal structure, allowing the first side surface to be constituted of the (100) plane and allowing the second side surface to he constituted of the (001) plane make an angle between the first side surface and the second side surface exceed 90°. Therefore, if a straight line extending from the connection of the first side surface and the second side surface along the direction perpendicular to the second side surface is virtually provided in the plan view of the upper surface of the gallium oxide substrate, this yields a triangular space between the straight line and the first side surface. Providing a gate pad in this space enables effective use of this space.

Another example of the switching element disclosed herein may further comprise: a main electrode located above the upper surface of the gallium oxide substrate; and a gate pad located above the upper surface of the gallium oxide substrate and connected to each gate electrode. The gallium oxide substrate may comprise: a third side surface parallel to the (100) plane; a fourth side surface perpendicular to both the (100) plane and the (010) plane. In the plan view of the upper surface of the gallium oxide substrate, the main electrode and the gate pad may be spaced apart from each other along a direction along which the (100) plane extends.

A spacing between the main electrode and the gate pad is prone to suffer from stress application. If this spacing extends along the (100) plane, the gallium oxide substrate becomes extremely easy to be cracked at this spacing. As described above, if the main electrode and the gate pad are disposed spaced apart from each other along the direction along which the (100) plane extends in the plan view of the upper surface of the gallium. oxide substrate, the spacing between the main electrode and the gate pad extends along the direction intersecting the (100) plane. Due to this, occurrence of cracks in the gallium oxide substrate can be suppressed in this spacing.

In an example of the switching element disclosed herein, in the plan view of the upper surface of the gallium oxide substrate, a length of the gallium oxide substrate in a direction perpendicular to the (100) plane may be shorter than a length of the gallium oxide substrate in a direction along which the (100) plane extends.

Allowing the gallium oxide substrate to have an elongated shape along the direction parallel to the (100) plane, as such, makes the gallium oxide substrate less likely to be cracked along the (100) plane.

An example of a method of manufacturing the switching element disclosed herein may comprise: polishing a surface of a gallium oxide wafer constituted of a gallium oxide crystal and having a diameter of 2 inches or more so as to thin the gallium oxide wafer; and manufacturing the switching element from the gallium oxide wafer.

When a gallium oxide wafer having a large diameter is thinned as such, cracking is likely to occur in the gallium oxide wafer during the manufacturing of the switching element. By adopting any of the above-mentioned structures of the switching elements, cracking of the gallium oxide wafer during the manufacturing can be suppressed.

While specific examples of the present disclosure have been described above in detail, these examples are merely illustrative and place no limitation on the scope of the patent claims. The technology described in the patent claims also encompasses various changes and modifications to the specific examples described above, The technical elements explained in the present description or drawings provide technical utility either independently or through various combinations. The present disclosure is not limited to the combinations described at the time the claims are filed. Further, the purpose of the examples illustrated by the present description or drawings is to satisfy multiple objectives simultaneously, and satisfying any one of those objectives gives technical utility to the present disclosure.

What is claimed is:

1. A switching element, comprising:
a gallium oxide substrate constituted of a gallium oxide crystal; and
a plurality of gate electrodes facing the gallium oxide substrate via a gate insulating film,
wherein
an upper surface of the gallium oxide substrate is parallel to a (010) plane of the gallium oxide crystal, and
in a plan view of the upper surface of the gallium oxide substrate, a longitudinal direction of each gate electrode intersects a direction along which a (100) plane of the gallium oxide crystal extends.

2. The switching element of claim 1, wherein
a plurality of trenches is provided in the upper surface of the gallium oxide substrate,
in the plan view of the upper surface of the gallium oxide substrate, a longitudinal direction of each trench intersects the direction along which the (100) plane extends, and
each gate electrode is located in. a corresponding one of the trenches.

3. The switching element of claim 1, further comprising a gate pad located above the upper surface of the gallium oxide substrate and connected to each gate electrode,
wherein
the gallium oxide substrate comprises:
a first side surface constituted of the (100) plane; and
a second side surface constituted of a (001) plane of the gallium oxide crystal, and
in the plan view of the upper surface of the gallium oxide substrate, the gate pad is located within a range between a straight line and the first side surface, the straight line extending from a connection of the first side surface and the second side surface along a direction perpendicular to the second side surface.

4. The switching element of claim 1, further comprising;
a main electrode located above the upper surface of the gallium oxide substrate; and
a gate pad located above the upper surface of the gallium oxide substrate and connected to each gate electrode,
wherein the gallium oxide substrate comprises:
a third side surface parallel to the (100) plane; and
a fourth side surface perpendicular to both the (100) plane and the (010) plane, and
in the plan view of the upper surface of the gallium oxide substrate, the main electrode and the gate pad are spaced apart from each other along the direction along which the (100) plane extends.

5. The switching element of claim 1, wherein, in the plan view of the upper surface of the gallium oxide substrate, a length of the gallium oxide substrate in a direction perpendicular to the (100) plane is shorter than a length of the gallium oxide substrate in the direction along which the (100) plane extends.

6. A method of manufacturing the switching element of claim 1, the method comprising:
polishing a surface of a gallium oxide wafer constituted of a gallium oxide crystal and having a diameter of 2 inches or more so as to thin the gallium oxide wafer; and
manufacturing the switching element from the gallium oxide wafer.
